(19) United States
(12) Patent Application Publication
(10) Pub. No.: US 2006/0238186 A1
(43) Pub. Date: Oct. 26, 2006

(54) Semiconductor device and temperature detection method using the same

(75) Inventors: Mutsuo Nishikawa, Matsumoto (JP); Katsumichi Ueyanagi, Matsumoto (JP)

Correspondence Address: KANESAKA BERNER AND PARTNERS LLP, SUITE 300, 1700 DIAGONAL RD, ALEXANDRIA, VA, 22314-2848, US

(73) Assignee: FUJI ELECTRIC DEVICE TECHNOLOGY CO., LTD, Tokyo (JP)

(21) Appl. No.: 11/342,877

(22) Filed: Jan. 31, 2006

(30) Foreign Application Priority Data
Apr. 22, 2005 (JP) 2005-125287

(51) Int. Cl. G01N 27/00

(52) U.S. Cl. 324/71.1

(57) ABSTRACT

A semiconductor apparatus has a temperature detecting section for detecting temperature with a semiconductor device formed in a semiconductor substrate; a temperature detector output terminal formed on the substrate for outputting a detection signal; a current generating device connected to the output terminal for supplying a driving current to the temperature detecting section; and a voltage measuring device connected to the output terminal for measuring the voltage of the output terminal. The apparatus detects temperature based on the voltage measured by the voltage measuring device when the driving current is supplied from the current generating device to the temperature detecting section. The apparatus is small, accurate, and easily manufactured at relatively low cost.

### BACKGROUND OF THE INVENTION AND RELATED ART STATEMENT

The present invention relates to a semiconductor device that conducts pressure detection and temperature detection mainly for controlling the engine of an automobile or a motorcycle. The present invention also relates to a temperature detection method.

Detection of the pressure and the temperature inside the engine used for an automobile or a motorcycle is indispensable for controlling the engine. FIG. 14 is a cross-sectional view schematically showing an engine for automobiles. The fundamental behaviors of an engine 40 shown in FIG. 14 will be described below.

First, air is fed to a cylinder 49 through an intake manifold 44. Fuel is injected from a fuel injection 46 and fed to cylinder 49 of engine 40 together with the air flowing through intake manifold 44.

In cylinder 49, a piston 50, valves 47 and a spark plug 48 synchronize each other to repeat a series of behaviors consisting of intake, compression, combustion (ignition and expansion) and exhaustion (exhaust gas) so that engine 40 may work as intended.

For controlling the engine speed or the engine power, the amount of the air flowing through intake manifold 44 and the amount of the fuel injected from fuel injection 46 are controlled. The mechanical valve for controlling the amount of the air flowing through intake manifold 44 is a throttle valve 43. Throttle valve 43 is opened and closed in response to the depression amount of an accelerator stick in the driver's seat to control the amount of the air flowing through intake manifold 44.

A pressure sensor 41 and a temperature sensor 42 are used to measure the amount of the air controlled by throttle valve 43 and flowing through intake manifold 4. The values measured by pressure sensor 41 and temperature sensor 42 are outputted to an engine control unit (hereinafter referred to as an “ECU”) 45. Based on the sensed values, ECU 45 controls the amount of the fuel injected from fuel injection 46 so that the efficiency of combustion in cylinder 49 may be improved and optimized.

Recently, the restrictions on the carbon dioxide emission amount and such environmental loads have become more severe year by year. Therefore, combustion efficiency improvement for the automobile and motorcycle engines is one of the most effective countermeasures for reducing the environmental loads. For improving the combustion efficiency, detecting means for measuring the pressure and the temperature of the intake manifold play important roles.

A semiconductor sensor that utilizes the piezoresistance effect of a diffused resistor and a semiconductor sensor that utilizes an electrostatic capacitor have been used for a pressure detecting means (hereinafter referred to as a “pressure sensor”) for measuring the pressure in the intake manifold of an internal combustion engine. A thermistor has been used generally for a temperature detecting means (hereinafter referred to as a “temperature sensor”) for measuring the intake manifold temperature.

JP P 2002-116108 A Publication discloses a sensor chip including a pressure sensor and a temperature sensor formed on a substrate. JP Hei 8 (1996)-226862 A Publication discloses a semiconductor apparatus that conducts temperature compensation of a pressure sensor using diodes connected in series. JP 2002-208677 A Publication discloses a temperature sensor that uses bipolar transistors for diodes.

However, since the thermistor and the pressure sensor are individual component parts, it is difficult to integrate the pressure sensor and the temperature sensor while reducing the sizes thereof. Moreover, many component parts increase the assembly steps, further increasing the assembly costs.

In the aforementioned references, the temperature detecting device is not a thermistor. The sensor chip disclosed in JP 2002-116108 A Publication uses a resistor for the temperature detecting device. When a resistor is used for temperature detection, more remarkable variations are caused in the temperature characteristics of the resistor by the manufacture thereof generally as the detection sensitivity thereof is made to be higher.

The semiconductor apparatus disclosed in JP Hei 8 (1996)-226862 A Publication and the temperature sensors disclosed in JP 2002-208677 A Publication use a diode for the temperature detecting device. However, the JP Hei 8 (1996)-226862 A Publication and the JP 2002-208677 A Publication do not describe anything regarding the detailed configuration or the operating conditions for obtaining the output characteristics suited for the temperature detecting device.

In view of the foregoing, the present invention obviates the problems described above, and it is objects of the invention to provide a small semiconductor apparatus having a structure that facilitates simple and easy manufacture thereof with low manufacturing costs, and to provide a temperature detection method that facilitates making the semiconductor apparatus work very accurately.

Further objects and advantages of the invention will be apparent from the following description of the invention and the associated drawings.

### SUMMARY OF THE INVENTION

According to a first embodiment of the invention a semiconductor apparatus includes a semiconductor substrate; a temperature detecting means including a semiconductor device formed in the semiconductor substrate, the temperature detecting means conducting temperature detection; an output terminal formed on the semiconductor substrate, the output terminal outputting the detection signal from the temperature detecting means to the outside; a current generating means connected to the output terminal, the current generating means supplying a driving current to the semiconductor device of the temperature detecting means; a voltage measuring means connected to the output terminal, the voltage measuring means measuring the voltage of the output terminal; the semiconductor device being formed of a diode. The semiconductor apparatus conducts temperature detection based on the voltage value measured by the voltage measuring means when the current generating means supplies the driving current of a predetermined value to the temperature detecting means.

According to one embodiment of the invention, the driving current is 0.1 μA or higher.

According to another aspect of the invention, the semiconductor device of the temperature detecting means further includes one or more diodes, and the diodes constituting the semiconductor device are connected in series to each other.

According to one embodiment, the diode is an npn-transistor, and the base electrode and the collector electrode thereof are short-circuited with each other.

According to another aspect of the invention, the npn-transistor includes a guard ring layer surrounding the base electrode, the collector electrode and the emitter electrode thereof to absorb the leakage current arising from the outside.

In one embodiment of the semiconductor apparatus, the npn-transistor includes a p-type semiconductor substrate; a surface portion in the p-type semiconductor substrate; an n-type well region formed in the surface portion; a p-type first base layer formed in the surface portion of the n-type well region; a p-type second base layer formed in the surface portion of the first base layer, the p-type second base layer being doped more heavily than the first base layer; an n-type emitter layer formed in the surface portion of the first base layer, the n-type emitter layer being doped heavily; an n-type first collector layer formed in the surface portion of the n-type well region, the n-type first collector layer surrounding the first base layer; an n-type second collector layer in the surface portion of the first collector layer, the n-type second collector layer comprising a more heavily doped n-type semiconductor than the first collector layer; and a guardring layer comprising a lightly doped p-type first semiconductor formed in the surface portion in the p-type semiconductor substrate, the lightly doped p-type first semiconductor surrounding the first collector layer and a p-type second semiconductor formed in the surface portion of the first semiconductor, the p-type second semiconductor being doped more heavily than the first semiconductor layer.

In another aspect of the invention, the semiconductor apparatus further includes a pressure detector formed on the semiconductor substrate, the pressure detector conducting pressure detection.

According to another embodiment of the invention, there is provided a method for detecting a temperature with one or more diodes formed in a semiconductor substrate. The method includes detecting a temperature based on the voltage measured across the one or more diodes when a driving current of a predetermined value is supplied to the one or more diodes.

According to the invention, it is possible to drive the temperature detecting means using a conventional system including a driving circuit for temperature detection without modifying or changing the conventional system configuration. The npn-transistor provided with a guard ring layer is prevented from being adversely affected by the leakage current flowing in from the adjacent device.

By employing only one or more diodes for a temperature detector, a small semiconductor apparatus that exhibits a high temperature detection sensitivity is realized. Since the temperature detector according to the invention can be mounted on a semiconductor substrate together with a pressure detector, a composite sensor having a necessary but minimum area is realized.

The semiconductor apparatus according to the invention, which employs one or more diodes having a predetermined structure for temperature detection, facilitates reducing the size thereof, reducing the manufacturing costs thereof, and improving the mass-productivity thereof.

### BRIEF DESCRIPTION OF THE DRAWINGS

FIG. 1 is a block diagram of a semiconductor apparatus according to a first embodiment of the invention.

FIG. 2 is an equivalent circuit diagram of the temperature detecting section in FIG. 1.

FIG. 3A is a cross-sectional view of an npn-transistor.

FIG. 3B is a top plan view of the npn-transistor.

FIG. 4 is a block circuit diagram of an over voltage protection circuit as an example of a CMOS IC that can be integrated into one chip with a diode.

FIG. 5 is a cross-sectional view of a p-type MOS transistor exhibiting a high breakdown voltage and constituting the over voltage protection circuit shown in FIG. 4.

FIG. 6 is a block circuit diagram illustrating the driving and measuring method for obtaining the output of the temperature detecting section.

FIG. 7 is a block circuit diagram illustrating the driving and measuring method illustrated in FIG. 6 in detail.

FIG. 8 is a plot relating the diode forward voltage Vf with the temperature.

FIG. 9 is a plot relating the diode forward voltage Vf with the bias current.

FIG. 10 shows a curve depicting the nonlinearity errors of the outputs from the temperature detector output terminal.

FIG. 11 shows a curve connecting the maximum points (the largest deviations) in FIG. 10 at the respective bias current values.

FIG. 12 shows a curve representing the ratio of the temperature conversion of the nonlinearity error, obtained by dividing the nonlinearity error value by the temperature coefficient, and the measurement temperature range.

FIG. 13 is a block diagram of a semiconductor apparatus according to a second embodiment of the invention.

FIG. 14 is a cross-sectional view schematically showing an engine for automobiles.

### DETAILED DESCRIPTION OF THE PREFERRED EMBODIMENTS

Now the invention will be described hereinafter in detail with reference to the accompanied drawing figures which illustrate the preferred embodiments of the invention.

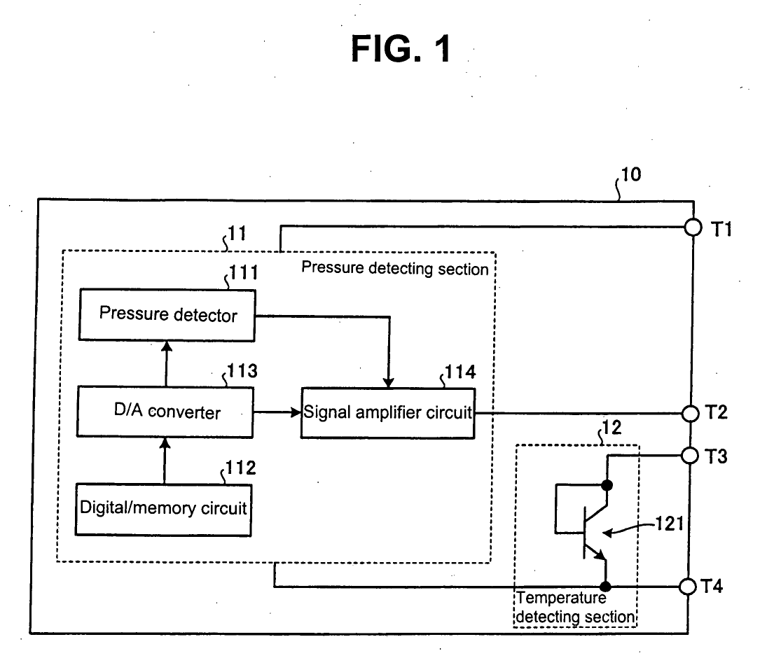

First, a semiconductor apparatus according to a first embodiment of the invention will be described. FIG. 1 is a block diagram of a semiconductor apparatus according to the first embodiment. The semiconductor apparatus 10 according to the first embodiment includes a pressure detecting section 11 arranged on a substrate, a temperature detecting section 12 arranged on the substrate, a power supply terminal T1, a pressure detector output terminal T2, a temperature detector output terminal T3, and a ground terminal T4. Pressure detecting section 11 includes a pressure detector 111, a digital/memory circuit 112, a D/A converter 113, and a signal amplifier circuit 114.

Pressure detector 111 in pressure detecting section 11 detects a pressure and outputs the detected pressure in the form of electrical signals. Digital/memory circuit 112 stores correction data for correcting the sensitivity, the offset and the temperature characteristics and feeds the correction data to D/A converter 113. D/A converter 113 corrects the sensitivity, the offset and the temperature characteristics. Signal amplifier circuit 114 amplifies the electrical signals outputted from pressure detector 111.

Pressure detector 111, digital/memory circuit 112, D/A converter 113 and signal amplifier circuit 114 constituting pressure detecting section 11 are connected to power supply terminal T1 and ground terminal T4. Pressure detecting section 11 is driven by the voltage supplied from the outside such that the voltage signal amplified by signal amplifier circuit 114 is outputted to the outside from pressure detector output terminal T2.

Temperature detecting section 12 includes an npn-transistor 121. The connection for npn-transistor 121 is made such that the base terminal and the collector terminal thereof are short-circuited with each other. The pn-junction between the base and the collector is biased always at the same potential by short-circuiting the base and collector terminals. Therefore, temperature detecting section 12 is configured such that the pn-junction between the base and the collector does not function but only the pn-junction between the base and the emitter functions electrically. In other words, npn-transistor 121 functions as a diode.

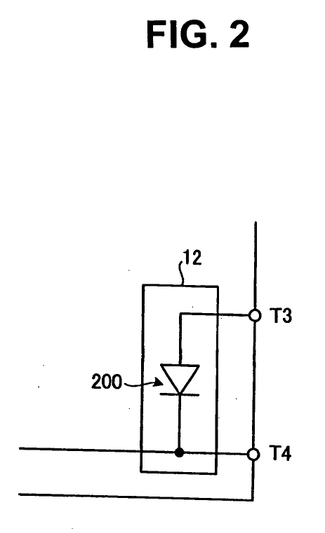

FIG. 2 is an equivalent circuit diagram of the temperature detecting section. As shown in FIG. 2, temperature detecting section 12 is equivalent to a diode 200. The short circuit terminal resulted from short-circuiting the base and collector terminals of npn-transistor 121 is equivalent to the anode terminal of diode 200. Similarly, the emitter terminal of npn-transistor 121 is equivalent to the cathode terminal of diode 200. The emitter terminal of npn-transistor 121 (cathode terminal of diode 200) is connected to ground terminal T4. The short circuit terminal of the base and the collector of npn-transistor 121 (anode terminal of diode 200) are connected to temperature detector output terminal T3. These connections facilitate outputting, from temperature detector output terminal T3, the so-called “diode forward voltage” Vf of npn-transistor 121.

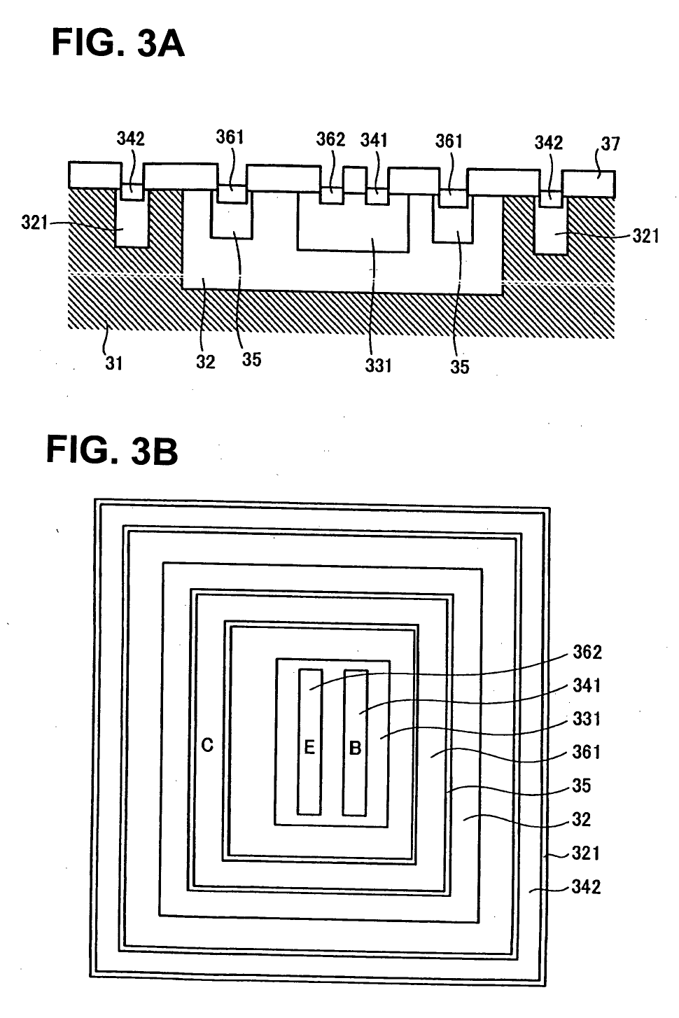

Now, npn-transistor 121 will be described below with reference to FIGS. 3A and 3B. FIG. 3A is a cross-sectional view of npn-transistor 121. FIG. 3B is a top plan view of npn-transistor 121. First, the structure of npn-transistor 121 will be described with reference to FIG. 3A.

According to the first embodiment, a p-type semiconductor is used for a substrate. Hereinafter, the substrate made of the p-type semiconductor will be referred to as the “p-type substrate 31.” An n-type well 32, which will work for a collector layer, is formed in p-type substrate 31. A p⁻-type base layer 331, which will work for a base layer, is formed in the surface portion of n-type well 32. An n⁺-type emitter layer 362, which will work for an emitter layer, is formed in the surface portion of p⁻-type base layer 331. A collector is formed of n-type well 32, a base is formed of p⁻-type base layer 331, and an emitter is formed of n⁺-type emitter layer 362 such that an npn-transistor (npn-transistor 121) of the so-called lateral-type is formed.

The term “p⁺-type” indicates that the impurity concentration for providing a p-type semiconductor with holes is high. The term “p⁻-type” indicates that the impurity concentration for providing a p-type semiconductor with holes is low. The term “n⁺-type” indicates that the impurity concentration for providing an n-type semiconductor with electrons is high. The term “n⁻-type” indicates that the impurity concentration for providing an n-type semiconductor with electrons is low. The impurity concentration is high or low relatively with reference to the semiconductor of the same conductivity type constituting the same device.

An n⁻-type collector layer 35 in the surface portion of n-type well 32 and an n⁺-type collector layer 361 in the surface portion of the n⁻-type collector layer 35 are formed for the pickup of (for the lead of an electrode for) n-type well 32. A p⁺-type base layer 341 in the surface portion of p⁻-type base layer 331 is formed for the pickup of p⁻-type base layer 331 that is formed in the surface portion of the n-type well 32.

In the planar arrangement shown in FIG. 3B, n⁺-type emitter layer (E) 362 and p⁺-type base layer (B) 341 are formed such that n⁺-type emitter layer 362 and p⁺-type base layer 341 are facing each other. The p⁻-type base layer 331 is formed such that p⁻-type base layer 331 is surrounding n⁺-type emitter layer 362 and p⁺-type base layer 341. The n⁺-type collector layer (C) 361 is formed such that n⁺-type collector layer 361 is surrounding p⁻-type base layer 331. Further, n-type well 32 is formed such that n-type well 32 is surrounding n⁺-type collector layer 361.

The n⁻-type collector layer 35 and n⁺-type collector layer 361, which are formed for the pickup of n-type well 32, are arranged in n-type well 32 like rings surrounding the base layer. Further, a p⁻-type guard ring layer 321 and a p⁺-type guard ring layer 342, which work as a guard ring, are arranged in the form of rings surrounding n-type well 32.

The uppermost surface of p-type substrate 31, excluding p⁺-type base layer 341, p⁺-type guard ring layer 342, n⁺-type collector layer 361 and n⁺-type emitter layer 362 for the electrode leads, is covered with an insulator layer 37.

Although not illustrated, n⁺-type collector layer 361 for the collector pickup and p⁺-type base layer 341 for the base pickup are short-circuited with each other with an aluminum (hereinafter referred to as “Al”) wiring connection such that an anode electrode is formed and connected to temperature detector output terminal T3. Similarly, n⁺-type emitter layer 362 and p⁺-type guard ring layer 342 are connected to ground terminal T4 via Al wiring.

In npn-transistor 121, a pnp transistor formed of p⁻-type base layer 331, n-type well 32 and p-type substrate 31 is structurally caused as a parasitic device in addition to the npn-transistor formed of the foregoing n-type well 32, p⁻-type base layer 331 and n⁺-type emitter layer 362. When the parasitic device as described above is made to work, a current (leakage current) will flow to p-type substrate 31, impairing the primary device characteristics. Furthermore, malfunction of the adjacent devices in the integrated circuit, latching-up, and such various hazards will be caused.

Therefore, it is necessary to employ countermeasures for preventing the parasitic pnp-transistor from working. The short-circuiting p⁻-type base layer 331 and n-type well 32 described above work effectively for the countermeasures against the parasitic pnp transistor. By biasing n-type well 32 and p⁻-type base layer 331 at the same potential, the base current of the parasitic pnp transistor is prevented from flowing. In addition, since a reverse bias voltage is applied between n-type well 32 and p-type substrate 31, n-type well 32 and p-type substrate 31 are isolated electrically from each other. As described above, the current leakage to p-type substrate 31 is effectively prevented from occurring.

The p⁻-type guard ring layer 321 and p⁺-type guard ring layer 342 are disposed such that guard ring layers 321 and 342 are surrounding p-type well 32 to absorb a faint leakage current caused in p-type substrate 31 so that the leakage current may be prevented from reaching the adjacent device. In other words, the guard ring layers are disposed to prevent any leakage current from entering the adjacent device.

The npn-transistor 121 is configured as described above. Since it is possible to form all the layers constituting npn-transistor 121 simultaneously through the process (that repeats ion implantation and subsequent diffusion) for manufacturing a complementary metal oxide semiconductor (hereinafter referred to as a “CMOS”), it is not necessary to add any specific manufacturing step at all.

In other words, the use of npn-transistor 121 makes it unnecessary to employ any technique for separating devices in an epitaxial wafer used generally in the BiCMOS, or any device separation technique that uses a SOI wafer and trench etching. Therefore, it is possible to integrate npn-transistor 121 into one chip with the general CMOS integrated circuit (hereinafter referred to as the “CMOS IC”) manufactured by repeating ion implantation and subsequent diffusion. Moreover, the manufacturing costs, at which the semiconductor apparatus according to the invention is manufactured, are advantageously prevented from increasing from the manufacturing costs, at which the general CMOS IC is manufactured.

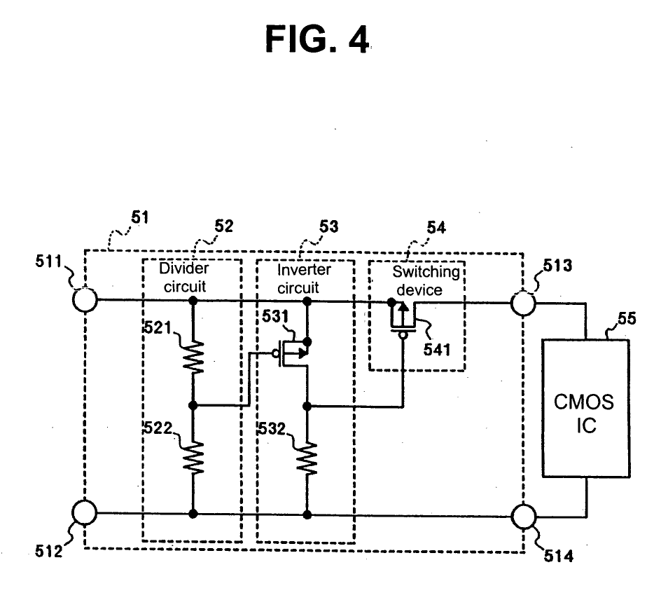

FIG. 4 is a block circuit diagram of an over voltage protection circuit as an example of a CMOS IC that can be integrated into one chip with a diode. The over voltage protection circuit 51 includes a voltage divider circuit 52, an inverter circuit 53 and a switching device 54. Over voltage protection circuit 51 is formed on a semiconductor substrate, on which a CMOS IC 55 protected by over voltage protection circuit 51 is formed. In FIG. 4, an external power supply terminal 511, to which a power supply voltage is supplied from the outside; a ground terminal 512, to which the ground potential is supplied from the outside; an internal power supply terminal 513, which supplies the power supply voltage applied to external power supply terminal 511 to CMOS IC 55; and a ground terminal 514 that supplies the ground potential to CMOS IC 55 are also shown.

Voltage divider circuit 52 includes, for example, a first resistor 521 and a second resistor 522. First resistor 521 is connected, at one end thereof, to external power supply terminal 511. First resistor 521 is connected, at the other end thereof, to one end of second resistor 522. The other end of second resistor 522 is connected to ground terminals 512 and 514.

Inverter circuit 53 includes, for example, a first p-type MOS transistor exhibiting a high breakdown voltage (hereinafter referred to as a “first PDMOS”) 531 and a third resistor 532. First PDMOS 531 is connected, at the source terminal thereof, to external power supply terminal 511. First PDMOS 531 is connected, at the gate terminal thereof, to the connection node, i.e. the voltage dividing point, of first and second resistors 521 and 522. First PDMOS 531 is connected, at the drain terminal thereof, to one end of third resistor 532. The other end of third resistor 532 is connected to ground terminals 512 and 514.

Switching device 54 includes, for example, a second p-type MOS transistor exhibiting a high breakdown voltage (hereinafter referred to as a “second PDMOS”) 541. Second PDMOS 541 is connected, at the source terminal thereof, to external power supply terminal 511. Second PDMOS 541 is connected, at the gate terminal thereof, to the drain terminal of first PDMOS 531. Second PDMOS 541 is connected, at the drain terminal thereof, to internal power supply terminal 513.

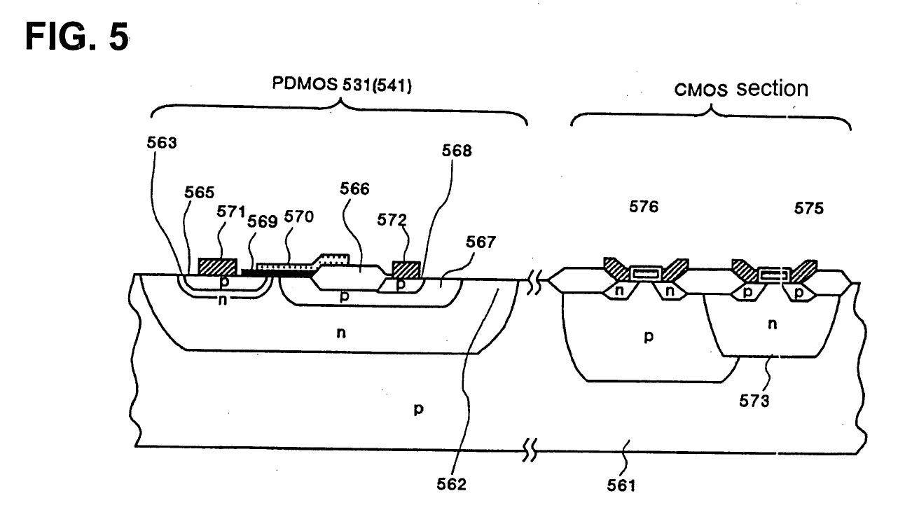

Now the structures of first PDMOS 531 and second PDMOS 541 will be described below. FIG. 5 is a cross-sectional view of a p-type MOS transistor exhibiting a high breakdown voltage and constituting the over voltage protection circuit shown in FIG. 4. On the left hand side of FIG. 5, an exemplary structure of PDMOS 531 (or 541) is shown. On the right hand side of FIG. 5, an n-channel MOSFET 576, made of an n-type semiconductor and having a CMOS structure, and a p-channel MOSFET 575, made of a p-type semiconductor and having a CMOS structure, are shown. The n-channel MOSFET 576 and p-channel MOSFET 575 are integrated into the same semiconductor substrate with first PDMOS 531 and second PDMOS 541. An n-type well 562 made of an n-type semiconductor is formed on the major surface side of a p-type substrate 561. A p-type offset region 567 and a p-type source region 565, both being made of a p-type semiconductor, are formed in the surface portion of p-type well region 562 such that p-type offset region 567 and p-type source region 565 are spaced apart by a narrow spacing.

A thick oxide film (hereinafter referred to as a “LOCOS”) 566 is formed selectively on a part of the surface of p-type offset region 567. A p-type drain region 568 is formed in the surface portion of p-type offset region 567 such that LOCOS 566 is between p-type drain region 568 and p-type source region 565 made of a p-type semiconductor. In n-type well region 562, an n-type base region 563, made of an n-type semiconductor and doped more heavily than n-type well region 562, is formed outside p-type source region 565. In FIG. 5, a gate insulator film 569, a gate electrode 570, a source electrode 571, and a drain electrode 572 are also shown.

The n-type well 32 (cf. FIG. 3A) is formed simultaneously with forming n-type well region 573 in p-channel MOSFET 575 and n-type well regions 562 in PDMOS 531 and PDMOS 541. Therefore, the mask and the ion implantation step solely for forming n-type well 32 are not necessary. The p⁻-type guard ring layer 321 and p⁻-type base layer 331 (cf. FIG. 3A) are formed simultaneously with forming p-type offset regions 567 in PDMOS 531 and PDMOS 541. Therefore, the mask and the ion implantation step solely for forming p -type guard ring layer 321 and p⁻-type base layer 331 are not necessary.

In a similar manner, n⁻-type collector layer 35 (cf. FIG. 3A) is formed simultaneously with forming n-type base layer 563. The p⁺-type base layer 341 and p⁺-type guard ring layer 342 (cf. FIG. 3A) are formed simultaneously with forming the source region and the drain region in p-channel MOSFET 575. The n⁺-type collector layer 361 and n⁺-type emitter layer 362 (cf. FIG. 3A) are formed simultaneously with forming the source region and the drain region in n-channel MOSFET 576. Insulator film 37 (cf. FIG. 3A) is formed simultaneously with forming LOCOS 566. Therefore, it is possible to form the npn-transistor without substantially adding any mask for exclusive use, or any specific manufacturing step.

Moreover, by providing npn-transistor 121 with guard ring layers, diode functions are realized using npn-transistor 121, npn-transistor 121 is made to work normally, and npn-transistor 121 is provided with a structure that does not affect the adjacent device integrated with npn-transistor 121. Therefore, the integration of npn-transistor 121 into one chip with the pressure sensor (pressure detecting section 11) and the temperature sensor (temperature detecting section 12) is facilitated. Semiconductor apparatus 10, which is a composite sensor capable of measuring the temperatures and pressures simultaneously, is obtained with low manufacturing costs.

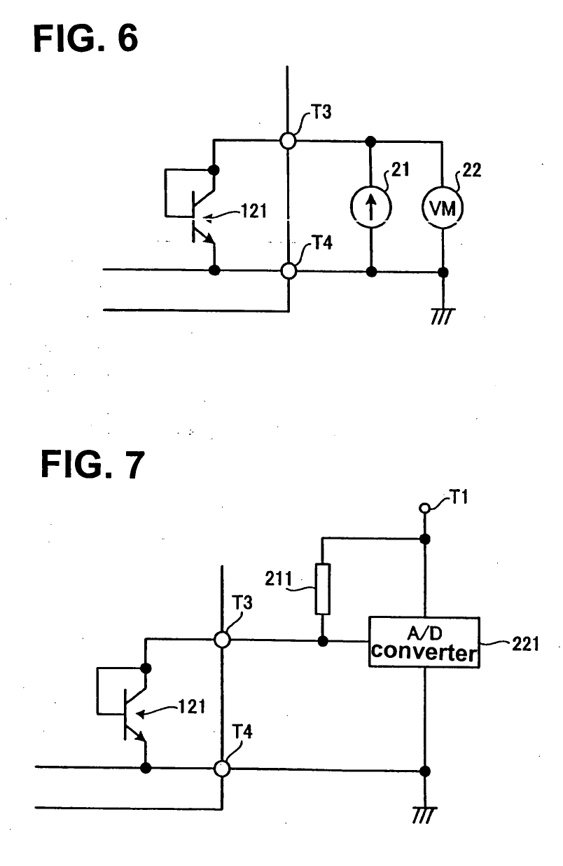

Now, the diode forward voltage Vf of npn-transistor 121, which is the output of temperature detecting section 12, will be described below. First, the method for measuring the diode forward voltage Vf will be described with reference to FIG. 6. FIG. 6 is a block circuit diagram describing the driving and measuring method for obtaining the output of the temperature detecting section.

Referring now to FIG. 6, a current generating means 21 and a voltage detecting means 22 are connected in parallel to each other between temperature detector output terminal T3 and ground terminal T4, between which npn-transistor 121 is connected, for obtaining the output of the temperature detecting section. By conducting current drive with current generating means 21, the voltage between temperature detector output terminal T3 and ground terminal T4, i.e. the diode forward voltage Vf of npn-transistor 121, can be measured with current detecting means 22.

FIG. 7 is a block circuit diagram for describing the driving and measuring method illustrated in FIG. 6 in detail. Referring now to FIG. 7, power supply terminal T1 is connected to temperature detector output terminal T3 via a resistor 211. An A/D converter 221 is connected between temperature detector output terminal T3 and ground terminal T4. A current, the value I thereof is obtained from (the power supply voltage—the voltage of temperature detector output terminal T3)/(the resistance value of resistor 211)=(the current value I), flows through npn-transistor 121. The voltage between temperature detector output terminal T3 and ground terminal T4 is measured by A/D converter 221.

The driving and measuring method described above is exemplary. Various alternatives are employable for obtaining the diode forward voltage Vf. For example, a band gap circuit that uses bipolar transistors or MOS's, a current mirror circuit that uses bipolar transistors or MOS's, and a current generating circuit that uses an operational amplifier may be employed for current generating means 21. In addition to A/D converter 221 that converts an analog quantity to a digital quantity, a signal amplifier circuit, an integrating circuit and such a converter circuit that uses an operational amplifier for a computing circuit to conduct analog/analog conversion may be used.

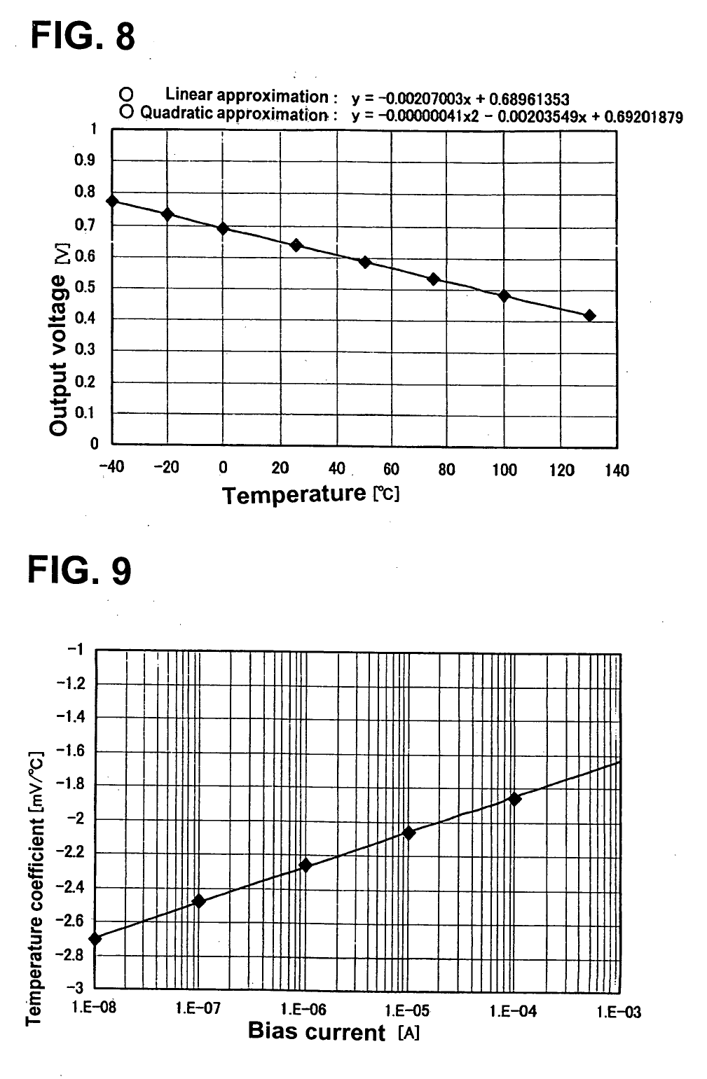

Now the relation between the conditions of the current generating means (driving current value) and the forward characteristics Vf will be described below with reference to FIGS. 8 and 9.

FIG. 8 is a plot relating the diode forward voltage Vf with the temperature. In FIG. 8, the vertical axis represents the output voltage in V and the horizontal axis the temperature in ° C. The diode forward voltage Vf decreases with increasing temperature. In other words, the diode forward voltage Vf exhibits negative temperature characteristics. The gradient of the linearly approximated temperature characteristics is called the “temperature coefficient.” (In FIG. 8, the linear approximation is shown, but the quadratic approximation described below the linear approximation is not.) The temperature coefficient is an index that indicates the sensitivity of the temperature sensor representing how high voltage change (V) will be caused by the temperature change of 1° C. For example, the temperature coefficient is −2.07 mV/° C. for the characteristics described in FIG. 8.

FIG. 9 is a plot relating the diode forward voltage Vf with the bias current. In FIG. 9, the vertical axis represents the temperature coefficient in mV/° C. and the horizontal axis the logarithmic bias current in A. As described in FIG. 9, the diode forward voltage Vf changes with the current made to flow to the diode (bias current). In detail, the temperature coefficient of the diode forward voltage Vf changes such that the absolute value thereof lowers (the value of the absolute temperature coefficient becomes closer to 0) in proportion to the logarithmic value (Log) of the bias current. The temperature coefficient is '2.07 mV/° C. for the bias current of 0.01 μA (1.E-08 in FIG. 9) and −1.6 mV/° C. for the bias current of 1 mA (1.E-03 in FIG. 9). Thus, the absolute value of the temperature coefficient becomes smaller as the bias current increases.

The smaller absolute temperature coefficient value means that the output voltage change per 1° C. is smaller. Since the small absolute temperature coefficient value means that the sensitivity of temperature detecting section 12 is low, the state, in which the absolute temperature coefficient value is small, should be avoided. Therefore, the results described in FIG. 9 indicate that a lower bias current is more preferable so as to realize temperature detecting section 12, i.e., so that the sensitivity thereof is high.

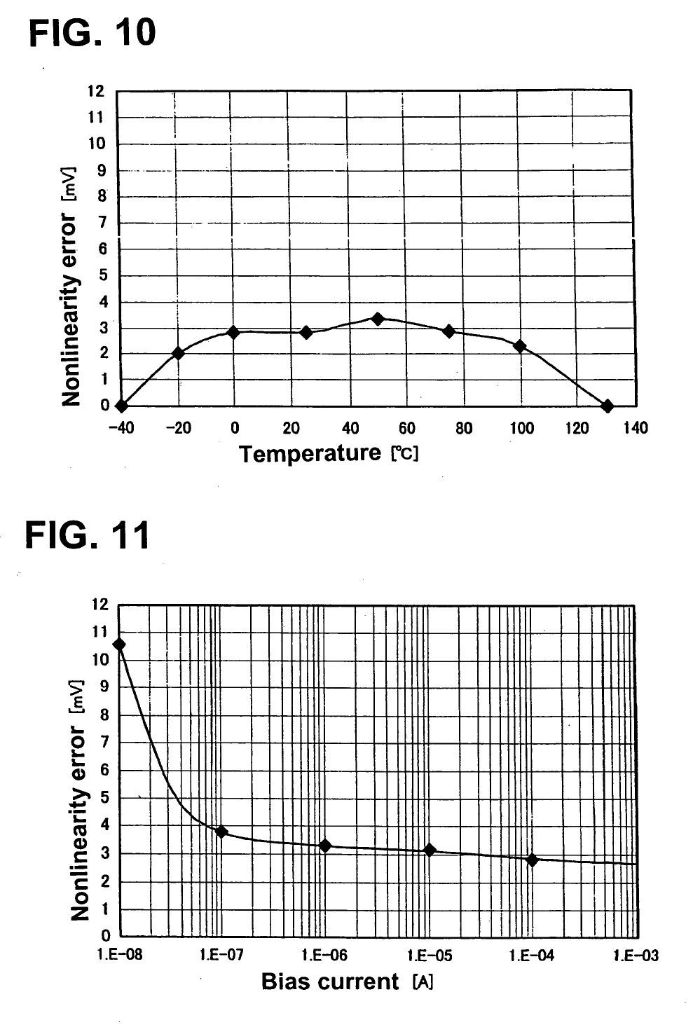

Now, the nonlinearity error, which is another index indicating the temperature detection performance, will be described below with reference to FIGS. 10 through 12. The temperature coefficient described above is the gradient, at which the linear approximation of the outputs changes with temperatures. The nonlinearity error is the value that represents how the plot of the outputs with reference to the temperature curves and deviates from the line (ideal line) that linearly approximates the plot of the outputs.

If described generally, various calculation methods are employable depending on the ways of expressing how the plot of the outputs with reference to the temperature curves and deviates from the linear approximation. Here, the nonlinearity error is expressed by the deviations of the diode forward voltages Vf's from the line connecting the diode forward voltages Vf's at −40° C. and 130° C. As the absolute value of the nonlinearity error is smaller, the sensor output changes more linearly and, therefore, the output characteristics of temperature detecting section 12 are more preferable.

FIG. 10 shows an exemplary curve depicting the nonlinearity errors of the outputs from temperature detector output terminal T3. In FIG. 10, the vertical axis represents the nonlinearity error in mV and the vertical axis the temperature in ° C. FIG. 10 describes the nonlinearity error values obtained from the deviations of the diode forward voltage values Vf's from the line connecting the diode forward voltages Vf's at −40° C. and 130° C.

The nonlinearity error of diode forward voltage Vf at the bias current of 10 μA (1.E-05 in FIG. 9) exhibits a maximum at 50° C. FIG. 10 indicates that the plot of the diode forward voltages Vf's curves in such a manner that the plot deviates from the ideal line connecting the diode forward voltages Vf's at −40° C. and 130° C. for +3 mV at 50° C.

FIG. 11 shows a curve connecting the maximum points (the largest deviations) in FIG. 10 at the respective bias current values. In FIG. 11, the vertical axis represents the nonlinearity error in mV and the vertical axis the logarithmic bias current in A. The nonlinearity error is smaller than 4 mV and almost saturates in the bias current range higher than 0.1 μA (1.E-07 in FIG. 11). The nonlinearity error becomes smaller as the bias current becomes higher. As the bias current exceeds 0.1 μA to the lower side, the nonlinearity error value becomes drastically larger, indicating that the output characteristics of temperature detecting section 12 are becoming worse with decreasing bias current.

Summarizing the temperature coefficient and the nonlinearity errors of the diode forward voltage Vf, for making the sensor sensitivity high, it is effective to decrease the bias current. However, the nonlinearity of the diode forward voltage becomes more remarkable as the bias current exceeds 0.1 μA to the lower side. Therefore, it is preferable to set the bias current to be 0.1 μA or higher. By setting the bias current to be 0.1 μA or higher, it is possible to provide the output of temperature detecting section 12 with excellent linearity.

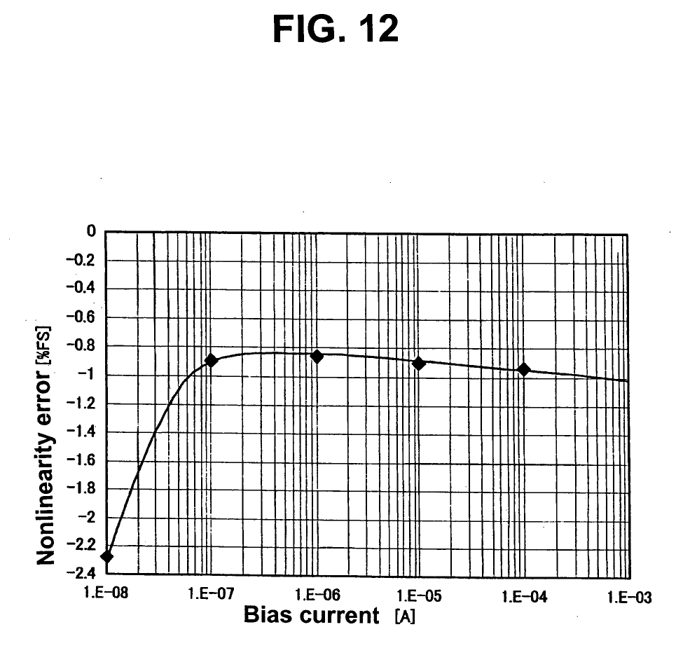

FIG. 12 shows a curve representing the ratio of the temperature conversion of the nonlinearity error, obtained by dividing the nonlinearity error value by the temperature coefficient, and the measurement temperature range (nonlinearity error in % full scale (FS): FS=170° C. (between −40° C. and 130° C.)). In FIG. 12, the vertical axis represents the nonlinearity error in % FS and the horizontal axis the logarithmic bias current in A.

As described earlier with reference to FIG. 11, the nonlinearity error in mV almost saturates in the current range higher than 0.1 μA. On the other hand, as described earlier with reference to FIG. 9, the absolute value of the temperature coefficient decreases linearly in the current range higher than 0.1 μA. In other words, although the nonlinearity error (the voltage error of the curve) in mV is almost constant, the voltage change per a temperature change of 1° C. decreases as the bias current increases. Therefore, if described relatively, the magnitude of the nonlinearity error in mV increases as the sensor sensitivity becomes higher. This specific feature is clearly shown in FIG. 12.

The value of the nonlinearity error with reference to the full measurement temperature range in %FS exhibits the best (maximum) at the bias current of 0.1 μA, and becomes worse gradually as the bias current increases. Therefore, it is possible to confine the nonlinearity error value of the temperature sensor within the range between 0% FS and −1% FS by setting the bias current within the range between 0.1 μA and 100 μA so that the output characteristics (accuracy) of temperature detecting section 12 may be improved.

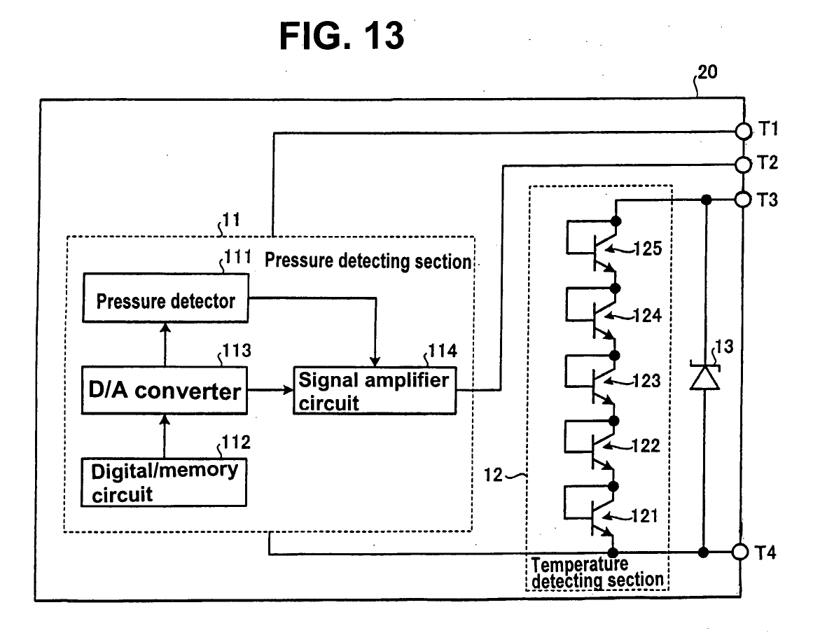

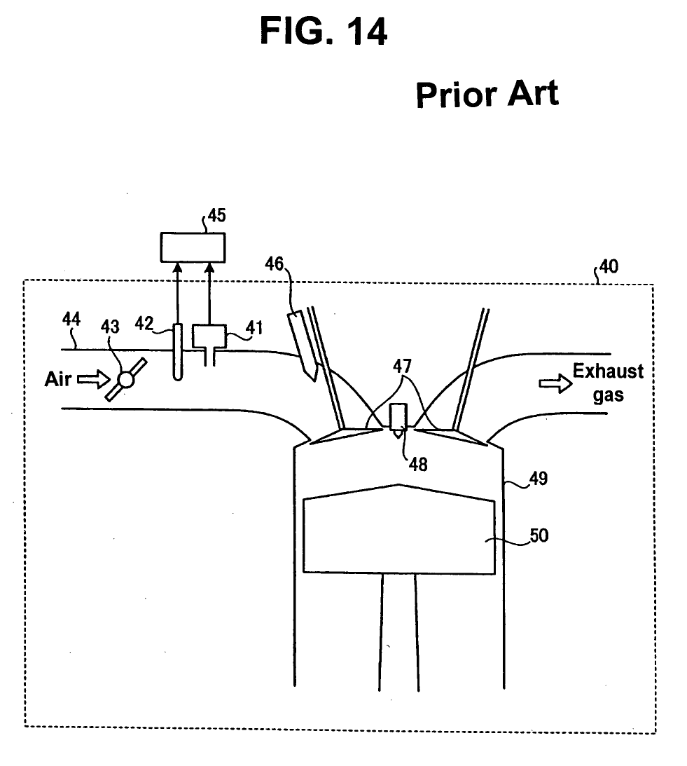

Now, a semiconductor apparatus according to a second embodiment of the invention will be described below. FIG. 13 is a block diagram of a semiconductor apparatus according to the second embodiment of the invention. The semiconductor apparatus 20 according to the second embodiment is different from semiconductor apparatus 10 according to the first embodiment in that temperature detecting section 12 in semiconductor apparatus 20 has a structure different from that in semiconductor apparatus 10, and a Zener diode 13 is connected between temperature detector output terminal T3 and ground terminal T4 in semiconductor apparatus 20 according to the second embodiment.

Temperature detecting section 12 in FIG. 13 includes npn-transistors 121, 122, 123, 124 and 125. The npn-transistors 121 through 125 are connected such that the respective bases and the respective collectors are short-circuited with each other. In other words, temperature detecting section 12 in FIG. 13 includes five diodes 200 (the npn-transistor, the base and collector thereof are short-circuited each other; cf. FIG. 2) described earlier in connection with semiconductor apparatus 10 according to the first embodiment. Further, Zener diode 13 is connected between temperature detector output terminal T3 and ground terminal T4 and in parallel to temperature detecting section 12.

Since the forward voltages Vf's of the diodes are added by connecting, in series, npn-transistors 121 through 125, the respective bases and the respective collectors thereof are short-circuited with each other, it is possible to set the change of the diode forward voltages Vf's caused by a temperature change (the temperature coefficient) to be five times as high as the temperature coefficient for one npn-transistor. In other words, semiconductor apparatus 20 according to the second embodiment facilitates improving the sensitivity of the temperature sensor. Zener diode 13, which conducts a Zener operation when surges are inputted from the outside, facilitates protecting temperature detecting section 12 against the surges.

As described above, semiconductor apparatus 20 according to the second embodiment may be used for a composite sensor that exhibits an excellent surge withstanding capability, includes a temperature sensor, the output sensitivity thereof is very high, and facilitates detecting temperatures and pressures. Although the semiconductor apparatus according to the second embodiment has been described as an example in connection with the temperature detecting section, including five npn-transistors 121 through 125, the number of the npn-transistors is not necessarily limited to five.

As described so far, the structure according to the invention, which includes temperature detecting section 12 formed of a diode based on npn-transistor 121, facilitates obtaining, in a necessary but minimum substrate area, a semiconductor apparatus that exhibits the functions equivalent to those of the thermistor, which exhibits a high temperature detection sensitivity, and facilitates detecting pressures and temperatures.

A conventional semiconductor apparatus that employs a resistor for temperature detection is not suited for mass production, since larger variations are caused as the temperature detection sensitivity is higher. The semiconductor apparatus according to the present invention that employs a diode, manufactured with less variations, has a structure suited for mass production.

Since the semiconductor apparatus according to the present invention facilitates using a conventional circuit that drives the thermistor without any change or any modification, a conventional detector that employs a thermistor may be replaced by the semiconductor apparatus according to the invention without changing the system of the apparatus (e.g. an automobile engine), in which the temperature and the pressure thereof are to be detected.

As described above, the semiconductor apparatus and the temperature detection method according to the invention are very advantageous for pressure and temperature detection in mass-produced equipment. The semiconductor apparatus and the temperature detection method according to the present invention are especially suited for pressure and temperature detection in the engines of automobiles and motorcycles.

The disclosure of Japanese Patent Application No. 2005-125287 filed on Apr. 22, 2005, is incorporated herein.

What is claimed is:

1. A semiconductor apparatus comprising:
a semiconductor substrate;
temperature detecting means comprising a semiconductor device with a diode, formed in the semiconductor substrate, the temperature detecting means conducting temperature detection;
an output terminal formed on the semiconductor substrate, the output terminal outputting a detection signal of the temperature detecting means to an outside;
current generating means connected to the output terminal, the current generating means supplying a driving current to the semiconductor device of the temperature detecting means; and
voltage measuring means connected to the output terminal, the voltage measuring means measuring the voltage of the output terminal so that a temperature detection is conducted based on a voltage value measured by the voltage measuring means when the current generating means supplies the driving current with a predetermined value to the temperature detecting means.

2. The semiconductor apparatus according to claim 1, wherein the driving current is 0.1 μA or higher.

3. The semiconductor apparatus according to claim 1, wherein the semiconductor device of the temperature detecting means comprises a plurality of diodes connected in series.

4. The semiconductor apparatus according to claim 1, wherein the diode comprises an npn-transistor having a base electrode and a collector electrode short-circuited with each other.

5. The semiconductor apparatus according to claim 4, wherein the npn-transistor further comprises an emitter electrode, and a guard ring layer for absorbing leakage current from outside the transistor, the guard ring layer surrounding the base electrode, the collector electrode, and the emitter electrode.

6. The semiconductor apparatus according to claim 4, wherein the npn-transistor comprises
a p-type semiconductor substrate;
a surface portion in the p-type semiconductor substrate;
an n-type well region formed in the surface portion;
a p-type first base layer formed in the surface portion of the n-type well region;
a p-type second base layer formed in the surface portion of the first base layer, the p-type second base layer being doped more heavily than the first base layer;
an n-type emitter layer formed in the surface portion of the first base layer, the n-type emitter layer being heavily doped;
an n-type first collector layer formed in the surface portion of the n-type well region, the n-type first collector layer surrounding the first base layer;
an n-type second collector layer in the surface portion of the first collector layer, the n-type second collector layer comprising a more heavily doped n-type semiconductor than the first collector layer; and
a guard ring layer comprising a lightly doped p-type first semiconductor formed in the surface portion in the p-type semiconductor substrate, the lightly doped p-type first semiconductor surrounding the first collector layer and a p-type second semiconductor formed in the surface portion of the first semiconductor, the p-type second semiconductor being doped more heavily than the first semiconductor layer.

7. The semiconductor apparatus according to claim 1, further comprising a pressure detector formed on the semiconductor substrate, the pressure detector conducting pressure detection.

8. A method of detecting a temperature with a diode formed in a semiconductor substrate, the method comprising:
detecting the temperature based on a voltage measured across the diode when a driving current of a predetermined value is supplied to the diode.

9. A method of detecting temperature comprising:
preparing a semiconductor apparatus comprising a semiconductor substrate; temperature detecting means for detecting temperature, the temperature detecting means comprising a semiconductor device with a diode, formed in the semiconductor substrate; an output terminal for outputting the detection signal of the temperature detecting means, the output terminal being formed on the semiconductor substrate; current generating means for supplying a driving current to the semiconductor device of the temperature detecting means, the current generating means being connected to the output terminal; and voltage measuring means for measuring voltage of the output terminal, the voltage measuring means being connected to the output terminal, supplying the driving current from the current generating means with a predetermined value to the temperature detecting means;
measuring a voltage with the voltage measuring means; and
detecting the temperature with the temperature detecting means based on the measured voltage.
